(19) United States
(12) Patent Application Publication
(10) Pub. No.: US 2025/0048717 A1
(43) Pub. Date: Feb. 6, 2025

(54) METHOD OF MANUFACTURING SEMICONDUCTOR DEVICE

(71) Applicant: SAMSUNG ELECTRONICS CO., LTD., Suwon-si (KR)

(72) Inventors: Hokyun AN, Suwon-si (KR); Kibum LEE, Suwon-si (KR); Jungmin CHO, Suwon-si (KR); Sunggyu CHOI, Suwon-si (KR)

(73) Assignee: SAMSUNG ELECTRONICS CO., LTD., Suwon-si (KR)

(21) Appl. No.: 18/745,614

(22) Filed: Jun. 17, 2024

(30) Foreign Application Priority Data
Aug. 2, 2023 (KR) 10-2023-0101120

(51) Int. Cl. H01L 21/8238; H01L 21/225; H01L 21/265; H01L 21/324

(52) U.S. Cl. CPC H01L 21/823821; H01L 21/2251; H01L 21/26513; H01L 21/324

(57) ABSTRACT

A method of manufacturing a semiconductor device includes forming, on a substrate, a semiconductor material layer including germanium, forming a diffusion material layer in an upper portion of the substrate adjacent to the semiconductor material layer by performing a first heat treatment on the semiconductor material layer, removing the semiconductor material layer, recrystallizing the diffusion material layer by performing a second heat treatment on the diffusion material layer, and forming a fin-type structure by removing at least a portion of the substrate and at least a portion of the diffusion material layer. The diffusion material layer includes germanium diffused from the semiconductor material layer. A germanium concentration in the fin-type structure decreases from an upper surface of the fin-type structure toward a lower surface of the fin-type structure along a vertical direction perpendicular to a top surface of the substrate.

### CROSS-REFERENCE TO RELATED APPLICATION

This application claims benefit of priority under 35 U.S.C. § 119 to Korean Patent Application No. 10-2023-0101120, filed on Aug. 2, 2023, in the Korean Intellectual Property Office, the disclosure of which is incorporated by reference herein in its entirety.

### BACKGROUND

### 1. Field

The present disclosure relates generally to a method of manufacturing a semiconductor device, and more particularly, to a method of manufacturing a semiconductor device including a fin-type structure.

### 2. Description of Related Art

Recently, as down-scaling of semiconductor devices increases, demand for increasing operation speed and/or operation accuracy of the semiconductor devices may also increase. In order to address these needs, research may be being conducted on semiconductor devices including fin-field effect transistors, gate-all-around field effect transistors, and/or multi-bridge channel field effect transistors.

There exists a need for further improvements in semiconductor manufacturing technology, as the need for down-scaling of semiconductor devices may be constrained by operation speed and/or operation accuracy of the semiconductor devices. Improvements are presented herein. These improvements may also be applicable to other semiconductor technologies.

### SUMMARY

One or more example embodiments of the present disclosure provide a method of manufacturing a semiconductor device with potentially improved manufacturing efficiency when compared to related semiconductor device manufacturing techniques.

According to an aspect of the present disclosure, a method of manufacturing a semiconductor device includes forming, on a substrate, a semiconductor material layer including germanium, forming a diffusion material layer in an upper portion of the substrate adjacent to the semiconductor material layer by performing a first heat treatment on the semiconductor material layer, removing the semiconductor material layer on which the first heat treatment has been performed, recrystallizing the diffusion material layer by performing a second heat treatment on the diffusion material layer, and forming a fin-type structure by removing at least a portion of the substrate and at least a portion of the diffusion material layer. The diffusion material layer includes at least a portion of germanium diffused from the semiconductor material layer by the performing of the first heat treatment. A germanium concentration in the fin-type structure decreases from an upper surface of the fin-type structure toward a lower surface of the fin-type structure along a vertical direction perpendicular to a top surface of the substrate.

According to an aspect of the present disclosure, a method of manufacturing a semiconductor device includes forming, on a substrate including a first area and a second area, a first mask pattern exposing the first area of the substrate, forming a semiconductor material layer including germanium on the first area exposed by the first mask pattern, forming a diffusion material layer in an upper portion of the first area of the substrate adjacent to the semiconductor material layer by performing a first heat treatment on the semiconductor material layer, removing the first mask pattern and the semiconductor material layer on which the first heat treatment has been performed, recrystallizing the diffusion material layer by performing a second heat treatment on the diffusion material layer, forming, on the substrate, a second mask pattern exposing at least a portion of the first area and at least a portion of the second area, forming, using the second mask pattern, a first fin-type structure on the first area, and forming, using the second mask pattern, a second fin-type structure on the second area. The diffusion material layer includes at least a portion of germanium diffused from the semiconductor material layer by the performing of the first heat treatment. An upper surface of the first fin-type structure and an upper surface of the second fin-type structure are located at a substantially similar vertical level.

According to an aspect of the present disclosure, a method of manufacturing a semiconductor device includes forming, on a substrate including a first area and a second area, a first mask pattern exposing the first area of the substrate, forming a semiconductor material layer including germanium and an anti-diffusion layer on the first area exposed by the first mask pattern, forming a diffusion material layer in an upper portion of the first area of the substrate adjacent to the semiconductor material layer by performing a first heat treatment on the semiconductor material layer, removing the semiconductor material layer, the anti-diffusion layer, and the first mask pattern, recrystallizing the diffusion material layer by performing a second heat treatment on the diffusion material layer on the first area, forming, on the substrate, a second mask pattern exposing at least a portion of the first area and at least a portion of the second area, forming, using the second mask pattern, a first fin-type structure in the first area by removing at least a portion of the substrate and at least a portion the diffusion material layer, and forming, using the second mask pattern, a second fin-type structure in the second area by removing at least another portion of the substrate. The diffusion material layer includes at least a portion of germanium diffused from the semiconductor material layer by the performing of the first heat treatment. A germanium concentration in the first fin-type structure decreases from an upper surface of the first fin-type structure toward a lower surface of the first fin-type structure along a vertical direction perpendicular to a top surface of the substrate. The upper surface of the first fin-type structure and an upper surface of the second fin-type structure are located at a substantially similar vertical level.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a plan view illustrating a semiconductor device, according to embodiments;

FIG. 2A is a cross-sectional view taken along line X1-X1′ of FIG. 1, according to embodiments;

FIG. 2B is a cross-sectional view taken along line X2-X2′ of FIG. 1, according to embodiments;

FIG. 2C is a cross-sectional view taken along line Y-Y′ of FIG. 1, according to embodiments;

FIG. 3 is a flowchart illustrating a method of manufacturing a semiconductor device, according to embodiments;

FIGS. 4A, 4B, 5, 6, 7, 8, 9A, 9B, 10A, 10B, 11A, 11B, 12A, 12B, 12C, 13, 14, 15A, 15B, and 15C are cross-sectional views illustrating operations of a method of manufacturing a semiconductor device, according to embodiments;

FIG. 16 is a view illustrating crystallinity in an embodiment and a comparative example, according to embodiments; and

FIG. 17 is a graph illustrating a result value of Raman analysis in an embodiment and a comparative example, according to embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is to be understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

As used herein, each of the terms “CdS”, “GaAs”, “GaP”, “HfO”, “InAs”, “InGaAs”, “InP”, “InSb”, “MON”, “SiBCN”, “SiBN”, “SiCN”, “SiGe”, “SiN”, “SiO”, “SiOC”, “SiOCN”, “SiON”, “TaN”, “TiAIC”, “TIN”, “ZnTe”, and the like may refer to a material made of elements included in each of the terms and is not a chemical formula representing a stoichiometric relationship.

Hereinafter, various embodiments of the present disclosure are described with reference to the accompanying drawings.

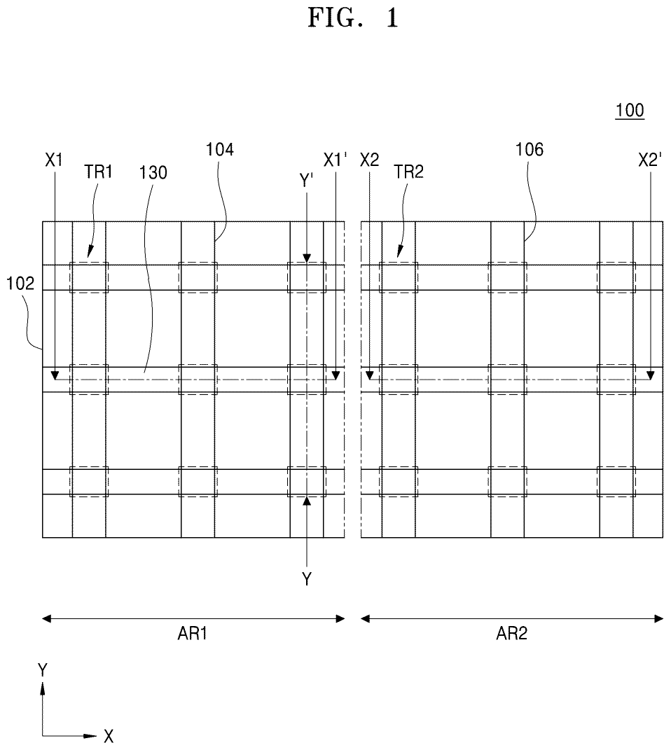

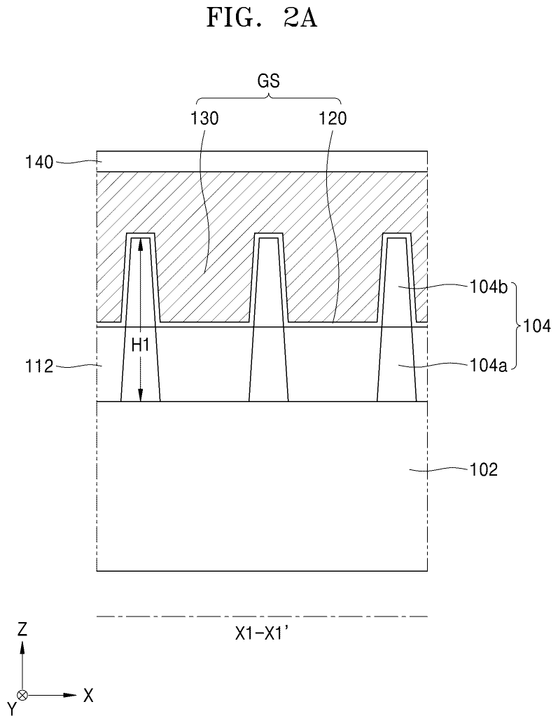

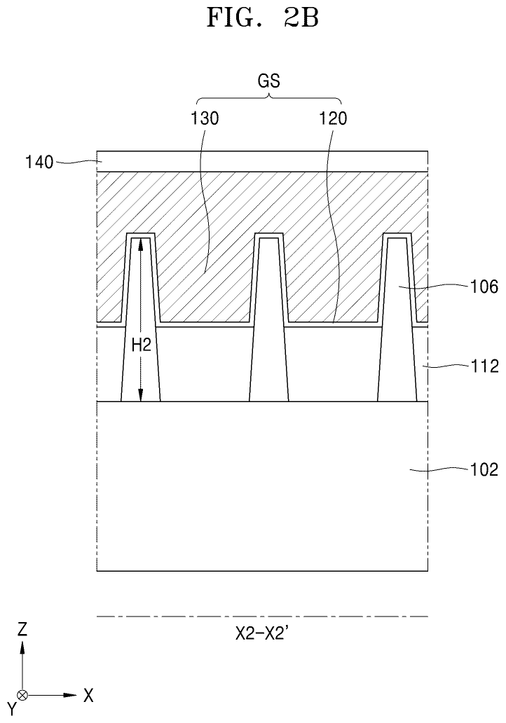

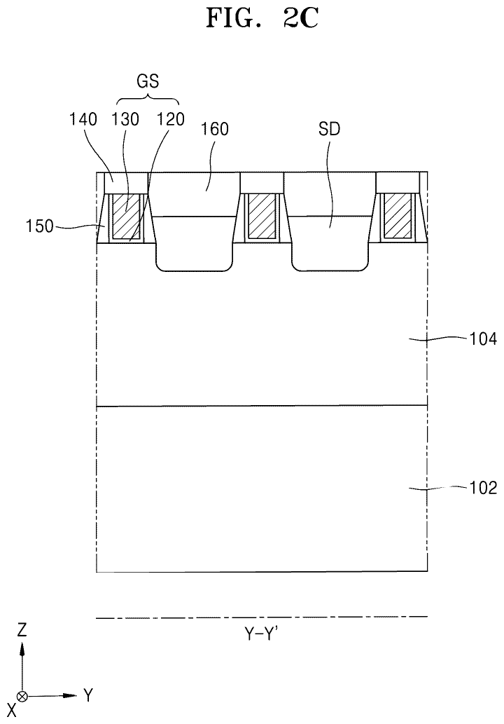

FIG. 1 is a plan view illustrating a semiconductor device, according to embodiments. FIG. 2A is a cross-sectional view taken along line X1-X1′ of FIG. 1, according to embodiments. FIG. 2B is a cross-sectional view taken along line X2-X2′ of FIG. 1, according to embodiments. FIG. 2C is a cross-sectional view taken along line Y-Y′ of FIG. 1, according to embodiments.

Referring to FIGS. 1, 2A, 2B, and 2C, a semiconductor device 100 may include a substrate 102 including a first area AR1 and a second area AR2, a first fin-type structure 104, and a second fin-type structure 106. The first fin-type structure 104 may be located (e.g., disposed) on the first area AR1 of the substrate 102, may protrude from the substrate 102 in a vertical direction (Z direction), and may extend along a second horizontal direction (Y direction). The second fin-type structure 106 may be located (e.g., disposed) on the second area AR2 of the substrate 102, may protrude from the substrate 102 in the vertical direction (Z direction), and may extend along the second horizontal direction (Y direction).

The first area AR1 and the second area AR2 of the substrate 102 may refer to different portions of the substrate 102, and may perform different operations on the substrate 102. The first area AR1 and the second AR2 may be spaced apart from each other and/or may be connected to each other. The first area AR1 and the second area AR2 may need different threshold voltages. For example, the first area AR1 may be and/or may include a P-channel metal-oxide semiconductor (PMOS) area where a P-type channel may be formed. The second area AR2 may be and/or may include an N-channel metal-oxide semiconductor (NMOS) area where an N-type channel may be formed.

A first transistor TR1 may be formed in the first area AR1 of the substrate 102, and a second transistor TR2 may be formed in the second area AR2. The first transistor TR1 and the second transistor TR2 may have different channel types. For example, the first transistor TR1 may be and/or may include a PMOS transistor where a P-type channel may be formed. The second transistor TR2 may be and/or may include an NMOS transistor where an N-type channel may be formed.

The substrate 102 may include a semiconductor material such as a group IV semiconductor material, a group III-V semiconductor material, or a group II-VI semiconductor material. For example, the group IV semiconductor material may include, but not be limited to, silicon (Si), germanium (Ge), silicon-germanium (SiGe), and the like. As another example, the group III-V semiconductor material may include, but not be limited to, gallium arsenide (GaAs), indium phosphide (InP), gallium phosphide (GaP), indium arsenide (InAs), indium antimony (InSb), indium gallium arsenide (InGaAs), and the like. As another example, the group II-VI semiconductor material may include, but not be limited to, zinc telluride (ZnTe) cadmium sulfide (CdS), and the like.

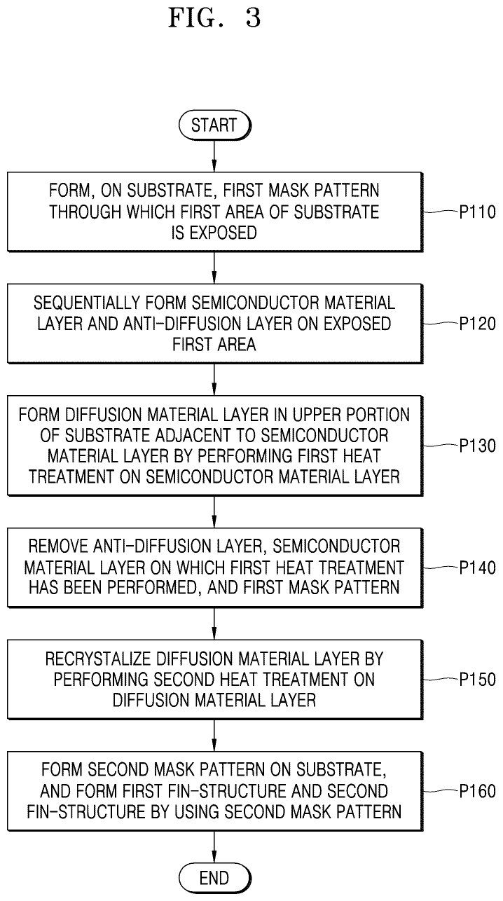

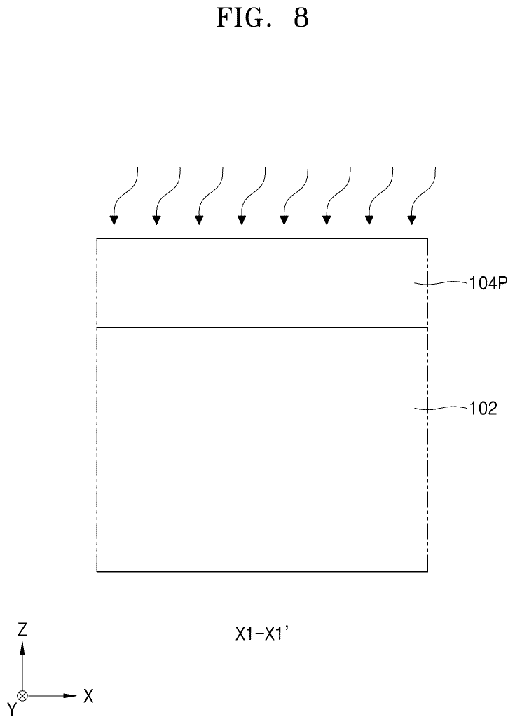

The first fin-type structure 104 may be located on the first area AR1 of the substrate 102. The first fin-type structure 104 may form a part of the first transistor TR1, and may function as a channel of the first transistor TR1. The first fin-type structure 104 may include a lower fin-type structure 104a and an upper fin-type structure 104b. The lower fin-type structure 104a may refer to, in a process of manufacturing the semiconductor device 100 described with reference to FIGS. 3 to 15C, a portion of the first fin-type structure 104 formed by etching a portion of the substrate 102 where germanium (Ge) is not diffused. Alternatively or additionally, the upper fin-type structure 104b may refer to, in the process of manufacturing the semiconductor device 100 described with reference to FIGS. 3 to 15C, the remaining portion of the first fin-type structure 104 formed by etching a diffusion material layer (e.g., diffusion material layer 104P of FIG. 8) formed in an upper portion of the substrate 102 by diffusion of germanium (Ge). Accordingly, the lower fin-type structure 104a may be formed of the same material as that of the substrate 102, and the upper fin-type structure 104b may be formed of a material of the substrate 102 and germanium (Ge). For example, each of the substrate 102 and the lower fin-type structure 104a may be formed of silicon (Si), and the upper fin-type structure 104b may be formed of silicon (Si) and germanium (Ge).

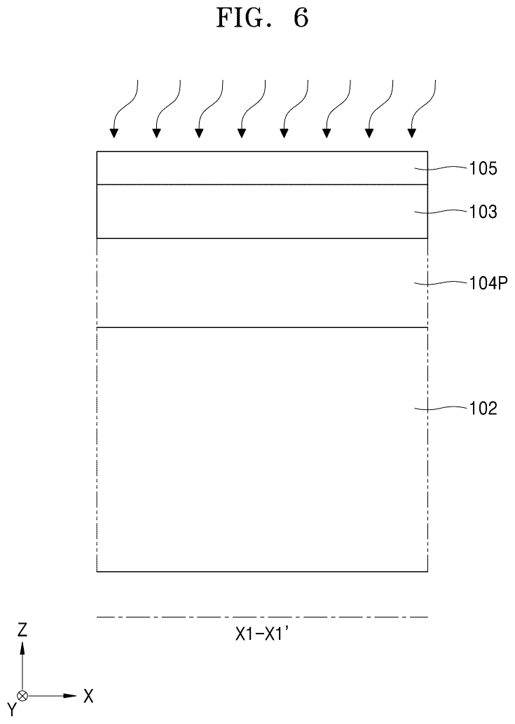

In embodiments, a germanium concentration of the upper fin-type structure 104b may vary according to a vertical level of the upper fin-type structure 104b. For example, a germanium concentration of the upper fin-type structure 104b may decrease from an upper surface of the upper fin-type structure 104b toward a lower surface of the upper fin-type structure 104b along the vertical direction (Z direction). As described with reference to FIG. 6, germanium (Ge) in the upper fin-type structure 104b may be diffused from a semiconductor material layer (e.g., semiconductor material layer 103 of FIG. 6) formed on a diffusion material layer (e.g., diffusion material layer 104P of FIG. 6) toward the diffusion material layer 104P along the vertical direction (Z direction). In embodiments, a germanium concentration of the upper fin-type structure 104b at the same vertical level may be the same and/or substantially similar across the same vertical level. For example, a germanium concentration on a surface of the upper fin-type structure 104b and a germanium concentration at a central portion of the upper fin-type structure 104b which are located at the same vertical level may be the same and/or substantially similar to each other. As described with reference to FIG. 6, germanium (Ge) may be diffused in the vertical direction (Z direction), rather than a horizontal direction (X direction or Y direction).

In embodiments, the lower fin-type structure 104a may be omitted. In such embodiments, the first fin-type structure 104 may include only the upper fin-type structure 104b.

The second fin-type structure 106 may be located on the second area AR2 of the substrate 102. The second fin-type structure 106 may form a part of the second transistor TR2, and may function as a channel of the second transistor TR2. The second fin-type structure 106 may be formed of the same material as that of the substrate 102 because the second fin-type structure 106 is formed by etching a portion of the substrate 102 in the process of manufacturing the semiconductor device 100 described with reference to FIGS. 3 to 15C. For example, each of the second fin-type structure 106 and the substrate 102 may be formed of silicon (Si).

In an embodiment, an upper surface of the first fin-type structure 104 and an upper surface of the second fin-type structure 106 may be located at the same vertical level and/or a substantially similar vertical level. In embodiments, a height H1 of the first fin-type structure 104 in the vertical direction (Z direction) and a height H2 of the second fin-type structure 106 in the vertical direction (Z direction) may be the same and/or substantially similar to each other. That is, in the process of manufacturing the semiconductor device 100 described with reference to FIGS. 3 to 15C, the first fin-type structure 104 may not be formed by forming a material layer including germanium (Ge) through an epitaxial growth process from a top surface of the substrate 102 and etching the material layer, but may be formed by forming a semiconductor material layer 103 (e.g., semiconductor material layer 103 of FIG. 6) including germanium (Ge) on a top surface of the substrate 102, diffusing the germanium (Ge) to an upper portion of the substrate 102 adjacent to the semiconductor material layer 103 to form a diffusion material layer (e.g., diffusion material layer 104P of FIG. 6) including germanium (Ge) in the upper portion, and etching the diffusion material layer 104P.

Device isolation films 112 may be located (e.g., disposed) on the substrate 102 on both side walls of the first fin-type structure 104 and the second fin-type structure 106. The device isolation films 112 may cover at least parts of the both side walls of the first fin-type structure 104 and the second fin-type structure 106. The device isolation films 112 may be formed of, for example, but not be limited to, an oxide film, a nitride film, and/or a combination thereof.

A gate structure GS may include a gate dielectric film 120 and a gate line 130. The gate structure GS may form parts of the first transistor TR1 and the second transistor TR2.

A plurality of gate lines 130 may be located on the first fin-type structure 104 and the second fin-type structure 106. Each of the plurality of gate lines 130 may extend along a first horizontal direction (X direction) intersecting the second horizontal direction (Y direction).

Each of the plurality of gate lines 130 may be formed of, for example, metal, metal nitride, metal carbide, and/or a combination thereof. The metal may be selected from among titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). However, the present disclosure is not limited in this regard, and the metal may be selected from among other metals having similar properties according to design constraints. The metal nitride film may be formed of and/or may include, for example, but not limited to, a titanium nitride (TiN) film, a tantalum nitride (TaN) film, a molybdenum nitride (MoN) film, and/or a combination thereof. The metal carbide may be formed of and/or may include, for example, but not be limited to, a titanium aluminum carbide (TiAIC). However, materials constituting the plurality of gate lines 130 are not limited thereto.

The gate dielectric film 120 may be located between the gate line 130 and the first fin-type structure 104 and between the gate line 130 and the second fin-type structure 106. The gate dielectric film 120 may have a structure in which an interface dielectric film and a high-k dielectric film are stacked. The interface dielectric film may be formed of a low-k dielectric material film having a dielectric constant of about nine (9) or less, such as, but not limited to, a silicon oxide (SiO) film, a silicon oxynitride (SiON) film, and/or a combination thereof. In embodiments, the interface dielectric film may be omitted. The high-k dielectric film may be formed of a material having a higher dielectric constant than a silicon oxide (SiO) film. For example, the high-k dielectric film may have a dielectric constant of about 10 to 25. As another example, the high-k dielectric film may be formed of and/or may include, but not limited be to, hafnium oxide (HfO).

The first transistor TR1 may be formed at intersections of the first fin-type structure 104 and the plurality of gate lines 130, and the second transistor TR2 may be formed at intersections of the second fin-type structure 106 and the plurality of gate lines 130.

On the first fin-type structure 104 and the second fin-type structure 106, both side walls of each of the plurality of gate lines 130 may be at least partially covered by insulating spacers 150. The insulating spacers 150 may be spaced apart from the gate line 130 with the gate dielectric film 120 therebetween. The insulating spacers 150 may be formed of and/or may include, for example, but not be limited to, silicon nitride (SiN), silicon oxide (SiO), silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), and/or a combination thereof.

A capping layer 140 may be formed on the gate structure GS. The capping layer 140 may at least partially cover top surfaces of the gate dielectric film 120, the gate line 130, and the insulating spacers 150. The capping layer 140 may be formed of and/or may include, for example, but not be limited to, silicon nitride (SIN), silicon oxide (SiO), silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), and/or a combination thereof.

A plurality of source/drain regions SD may be formed on both side walls of the gate structure GS with the gate structure GS therebetween. The plurality of source/drain regions SD may be formed of and/or may include, for example, but not be limited to, an epitaxially grown semiconductor layer. The plurality of source/drain regions SD may be formed of and/or may include, for example, but not be limited to, a combination of a group IV element semiconductor and a group IV component semiconductor.

At least a part of each of the plurality of source/drain regions SD may be doped with a P-type dopant. In embodiments, the P-type dopant may be selected from among boron (B), gallium (Ga), and the like.

An inter-gate insulating film 160 may be located between adjacent gate structures GS. The inter-gate insulating film 160 may cover each of the plurality of source/drain regions SD and the insulating spacers 150. The inter-gate insulating film 160 may be formed of and/or may include, a silicon nitride (SiN) film, a silicon oxide (SiO) film, silicon oxynitride (SiON), silicon oxycarbonitride (SiOCN), and/or a combination thereof.

The semiconductor device 100, according to embodiments, may include the first fin-type structure 104 including the lower fin-type structure 104a and the upper fin-type structure 104b in the first area AR1 of the substrate 102. The upper fin-type structure 104b may include germanium (Ge). As described with reference to FIGS. 3 to 15C, the upper fin-type structure 104b may not be formed by forming a material layer including germanium (Ge) through an epitaxial growth process from a top surface of the substrate 102 and etching the material layer, but may be formed by forming the semiconductor material layer (e.g., semiconductor material layer 103 of FIG. 6) including germanium (Ge) on a top surface of the substrate 102, diffusing the germanium (Ge) to an upper portion of the substrate 102 adjacent to the semiconductor material layer 103 to form the diffusion material layer (e.g., diffusion material layer 104P of FIG. 6) including germanium (Ge) on the upper portion, and etching the diffusion material layer 104P. As a result of the upper fin-type structure 104b being formed without using epitaxial growth, manufacturing costs of the semiconductor device 100 may potentially be reduced, thereby improving the manufacturing efficiency of the semiconductor device 100 when compared to manufacturing of a related semiconductor device.

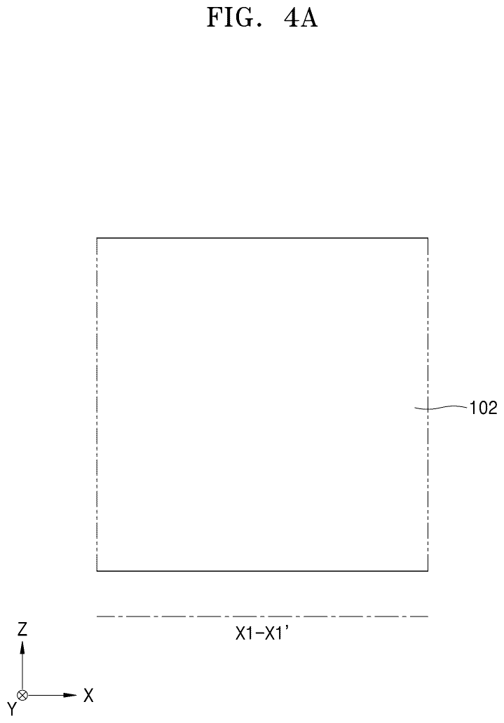

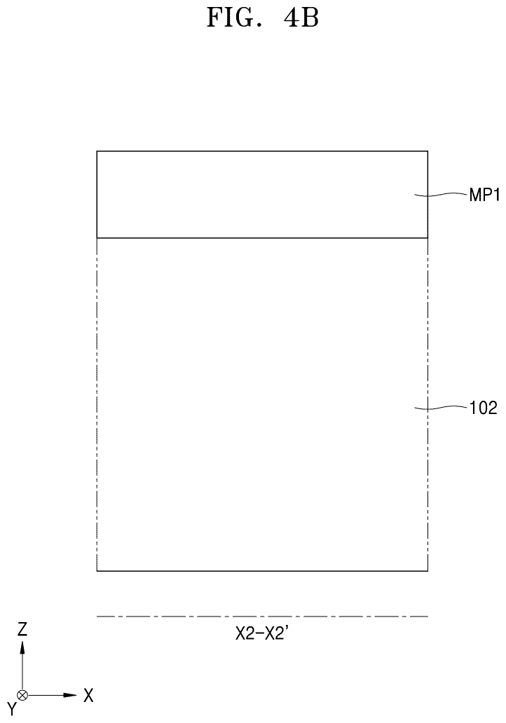

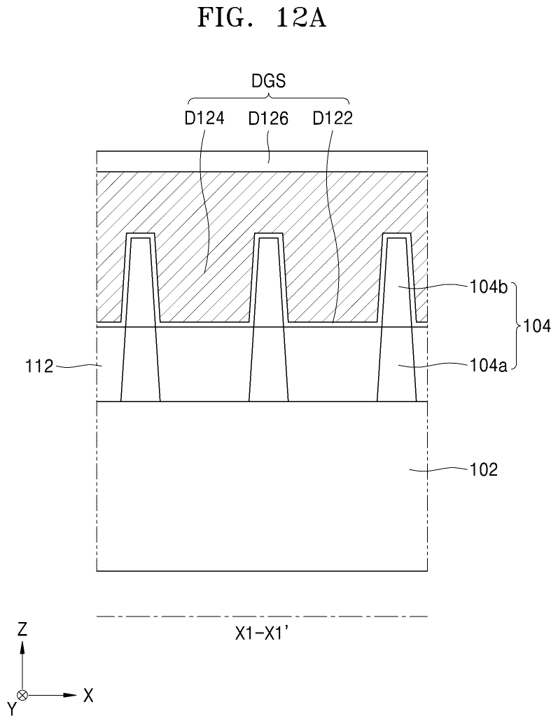

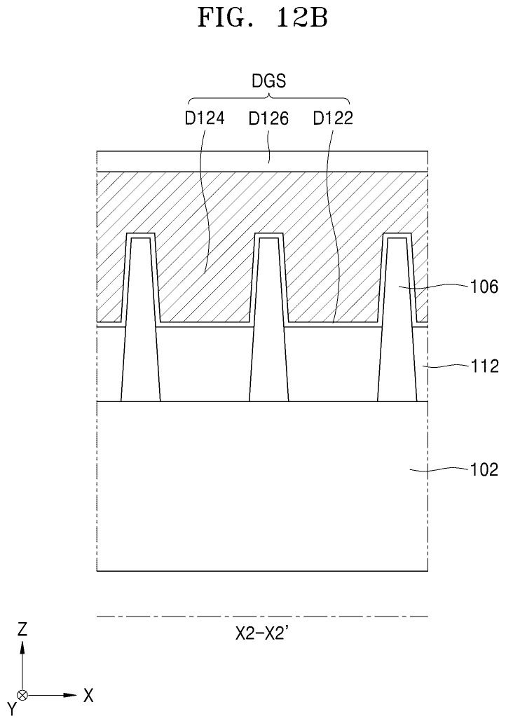

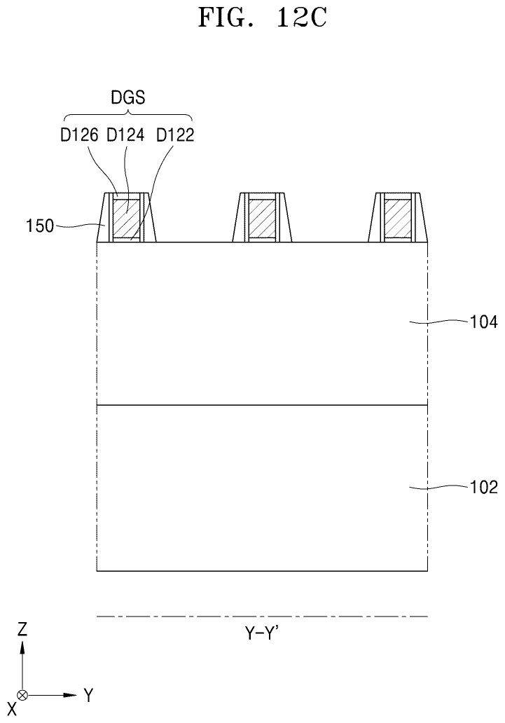

FIG. 3 is a flowchart illustrating a method of manufacturing the semiconductor device 100, according to embodiments. FIGS. 4A, 4B, 5, 6, 7, 8, 9A, 9B, 10A, 10B, 11A, 11B, 12A, 12B, 12C, 13, 14, 15A, 15B, and 15C are cross-sectional views illustrating operations of a method of manufacturing a semiconductor device, according to embodiments. Referring to FIGS. 4A, 5, 6, 7, 8, 9A, 10A, 11A, 12A, and 15A, the diagrams illustrate cross-sectional views taken along line X1-X1′ of FIG. 1. FIGS. 4B, 9B, 10B, 11B, 12B, and 15B are cross-sectional views taken along line X2-X2′ of FIGS. 1 and 2. FIGS. 12C, 13, 14, and 15C are cross-sectional views taken along line Y-Y′ of FIG. 1.

Referring to FIGS. 3, 4A, and 4B, a first mask pattern MP1 may be formed on the substrate 102 (operation P110). The first mask pattern MP1 may have an opening through which the first area (e.g., first area AR1 of FIG. 1) is exposed. Accordingly, the first area AR1 of the substrate 102 may be exposed by the first mask pattern MP1, and the second area (e.g., second area AR2 of FIG. 2) of the substrate 102 may be covered by the first mask pattern MP1.

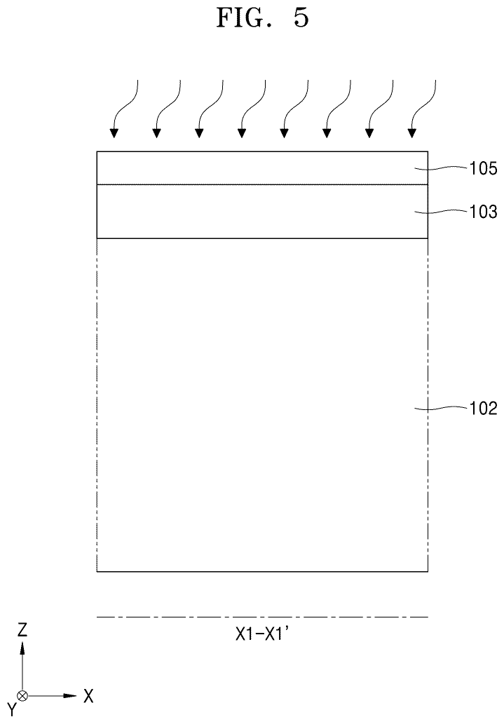

Referring to FIGS. 3 and 5, in a resultant structure of FIGS. 4A and 4B, the semiconductor material layer 103 and an anti-diffusion layer 105 may be sequentially formed on the first area AR1 of the substrate 102 exposed by the first mask pattern MP1 (operation P120).

The semiconductor material layer 103 may include at least one of silicon (Si) and germanium (Ge). In embodiments, a germanium concentration in the semiconductor material layer 103 may range from about 5 atomic concentration % to about 50 atomic concentration %. For example, the concentration of a third semiconductor material may range from about 5 atomic concentration % to about 50 atomic concentration %, from about 10 atomic concentration % to about 50 atomic concentration %, from about 10 atomic concentration % to about 30 atomic concentration %, and from about 20 atomic concentration % to about 30 atomic concentration %.

In embodiments, a thickness of the semiconductor material layer 103 in the vertical direction (Z direction) may range from about 30 angstroms (Å) to about 200 Å. For example, a thickness of the semiconductor material layer 103 in the vertical direction (Z direction) may be about 100 Å. A thickness of the semiconductor material layer 103 may vary within the above range according to a thickness in the vertical direction (Z direction) of the upper fin-type structure 104b to be formed in a process described with reference to FIGS. 3 to 15C.

In embodiments, the semiconductor material layer 103 may be formed as a plurality of semiconductor material layers 103. For example, the semiconductor material layer 103 may be formed as a plurality of semiconductor material layers including silicon (Si) and germanium (Ge), and the plurality of semiconductor material layers may be a plurality of semiconductor material layers having different germanium concentrations.

In embodiments, the semiconductor material layer 103 may be formed using a thermal deposition process and/or a plasma deposition process. The thermal deposition process may be and/or may include, for example, at least one of a thermal chemical vapor deposition (CVD) and a thermal atomic layer deposition (ALD). The plasma deposition process may be and/or may include, for example, at least one of a plasma-enhanced chemical vapor deposition (PECVD) and a plasma-enhanced atomic layer deposition (PEALD). In additional or optional embodiments, the semiconductor material layer 103 may be formed by using a doping process. For example, the semiconductor material layer 103 may be formed by forming a silicon material layer and implanting germanium (Ge) ions into the silicon material layer.

In embodiments, the anti-diffusion layer 105 may be formed by using a deposition process. The deposition process may be and/or may include, for example, CVD, physical vapor deposition, and/or ALD. In embodiments, the anti-diffusion layer 105 may be formed of and/or may include, but may not be limited to, an oxide, a nitride, a polysilicon, and/or a combination thereof. The oxide may be and/or may include, for example, silicon oxide (SiO). The nitride may be and/or may include, for example, silicon nitride (SIN).

Referring to FIGS. 3 and 6, in a resultant structure of FIG. 5, the diffusion material layer 104P may be formed in an upper portion of the substrate 102 adjacent to the semiconductor material layer 103 by performing a first heat treatment process on the semiconductor material layer 103 (operation P130). The diffusion material layer 104P may refer to a portion of the substrate 102 where germanium (Ge) is diffused from the semiconductor material layer 103. As a result of the first heat treatment process, germanium (Ge) included in the semiconductor material layer 103 may be diffused to the upper portion of the substrate 102 adjacent to the semiconductor material layer 103. Accordingly, the diffusion material layer 104P including germanium (Ge) and silicon (Si) of the substrate 102 may be formed in the upper portion of the substrate 102 adjacent to the semiconductor material layer 103. In an embodiment, the anti-diffusion layer 105 may prevent germanium (Ge) included in the semiconductor material layer 103 from being diffused upward from the semiconductor material layer 103 during the first heat treatment process.

In embodiments, a germanium concentration in the diffusion material layer 104P may vary according to a vertical level of the diffusion material layer 104P. For example, a germanium concentration of the diffusion material layer 104P may decrease away from a top surface of the diffusion material layer 104P. The decreasing germanium concentration may be caused by a diffusion direction of the germanium (Ge) being from the top surface of the diffusion material layer 104P toward a bottom surface of the diffusion material layer 104P.

In embodiments, the first heat treatment process may be performed at a temperature range between about 600 degrees Centigrade (° C.) and about 900° C. For example, the first heat treatment process may be performed at a temperature of about 800° C. However, the present disclosure is not limited in this regard.

In embodiments, the first heat treatment process may be performed for a time duration between about 5 minutes and about 20 minutes. For example, the first heat treatment process may be performed for about 10 minutes. However, the present disclosure is not limited in this regard.

A temperature and a time at and for which the first heat treatment process is performed may vary according to a thickness in the vertical direction (Z direction) of the upper fin-type structure 104b to be formed in a process described with reference to FIGS. 3 to 15C.

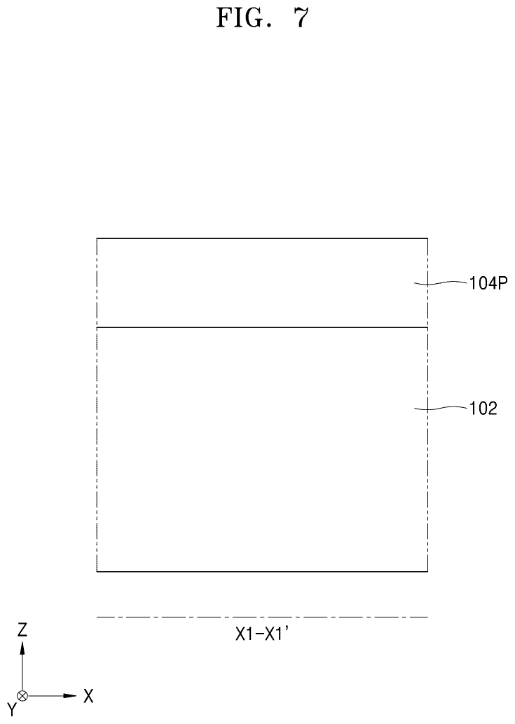

Referring to FIGS. 3 and 7, in a resultant structure of FIG. 6, the first mask pattern MP1, the anti-diffusion layer 105, and the semiconductor material layer 103 may be sequentially removed (operation P140). The first mask pattern MP1, the anti-diffusion layer 105, and the semiconductor material layer 103 may be removed by using, for example, an etching process. As the first mask pattern MP1, the anti-diffusion layer 105, and the semiconductor material layer 103 are removed, the diffusion material layer 104P formed in the upper portion of the substrate 102 may be exposed.

Referring to FIGS. 3 and 8, in a resultant structure of FIG. 7, the silicon (Si) and germanium (Ge) included in the diffusion material layer 104P may be recrystallized, by performing a second heat treatment process on the diffusion material layer 104P formed in the upper portion of the substrate 102 in the first area AR1 of the substrate 102 (operation P150). As a result of the second heat treatment process, a crystallinity property of the diffusion material layer 104P may be improved.

In embodiments, the second heat treatment process may be and/or may include at least one of spike rapid thermal annealing (RTA), laser annealing, and flash lamp annealing. For example, the second heat treatment process may be and/or may include a spike RTA process.

In embodiments, the second heat treatment process may be performed for time duration less than or equal to about 3 seconds. For example, the second heat treatment process may be performed for about 1 nanosecond (nsec). A time for which the second heat treatment process is performed may vary according to a type of the second heat treatment process and/or design constraints.

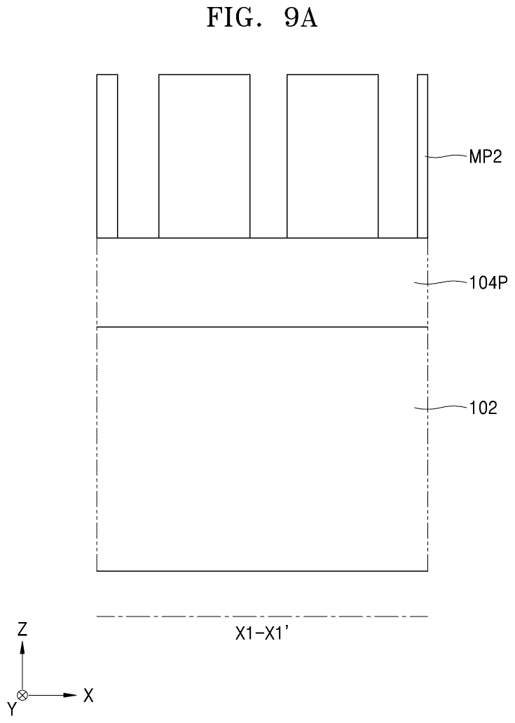

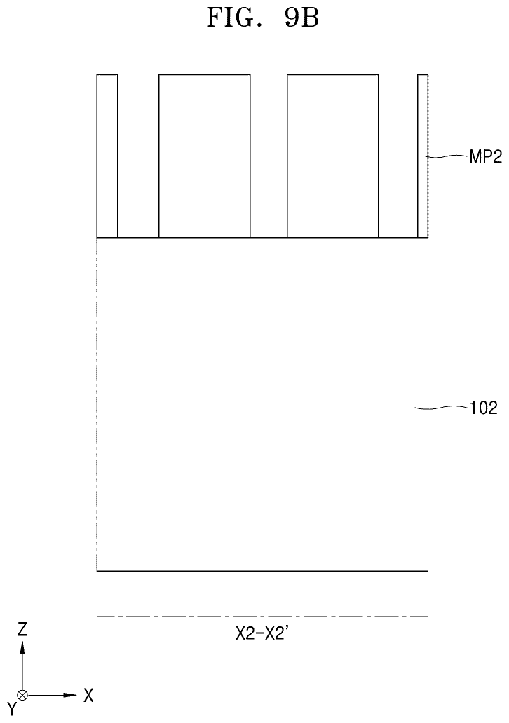

Referring to FIGS. 3, 9A, and 9B, in a resultant structure of FIG. 8, a second mask pattern MP2 may be formed on the substrate 102 (operation P160). The second mask pattern MP2 may include a plurality of openings through which a part of the first area AR1 and a part of the second area AR2 are exposed. The plurality of openings may extend along the second horizontal direction (Y direction).

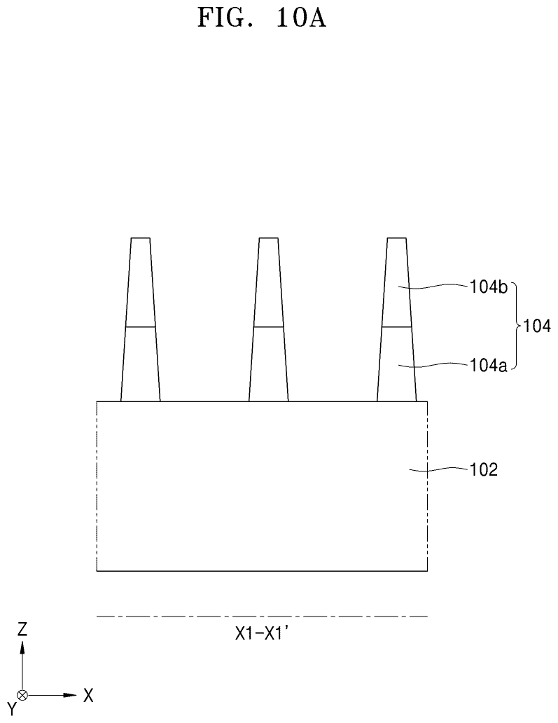

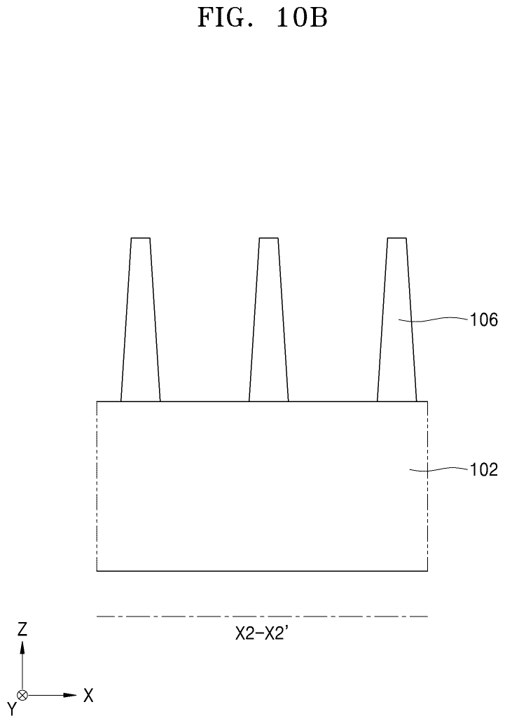

Referring to FIGS. 3, 10A, and 10B, in a resultant structure of FIGS. 9A and 9B, the first fin-type structure 104 may be formed by etching a part of each of the diffusion material layer 104P and the substrate 102 in the first area AR1 and the second fin-type structure 106 may be formed by etching the substrate 102 in the second area AR2 by using the second mask pattern MP2 (operation P160).

The first fin-type structure 104 may include the upper fin-type structure 104b formed by etching the diffusion material layer 104P and the lower fin-type structure 104a formed by etching the substrate 102. Accordingly, the upper fin-type structure 104b may be formed of germanium (Ge) and silicon (Si), and the lower fin-type structure 104a may be formed of silicon (Si). The second fin-type structure 106 may be formed by etching the substrate 102, and may include silicon (Si).

In embodiments, a height of the first fin-type structure 104 in the vertical direction (Z direction) and a height of the second fin-type structure 106 in the vertical direction (Z direction) may be the same height and/or may be substantially to each other. *** This is because The heights of the first fin-type structure 104 and the second fin-type structure 106 may be at least substantially similar as a result of the first fin-type structure 104 not being formed by forming a material layer including germanium (Ge) through an epitaxial growth process from a top surface of the substrate 102 and etching the material layer, but being formed by forming the semiconductor material layer 103 including germanium (Ge) on a top surface of the substrate 102, diffusing the germanium (Ge) to an upper portion of the substrate 102 adjacent to the semiconductor material layer 103 to form the diffusion material layer 104P including germanium (Ge) in the upper portion, and etching the diffusion material layer 104P.

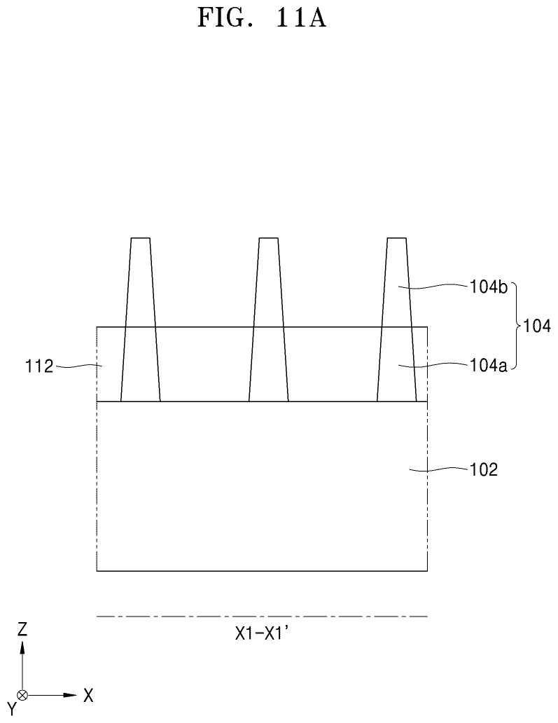

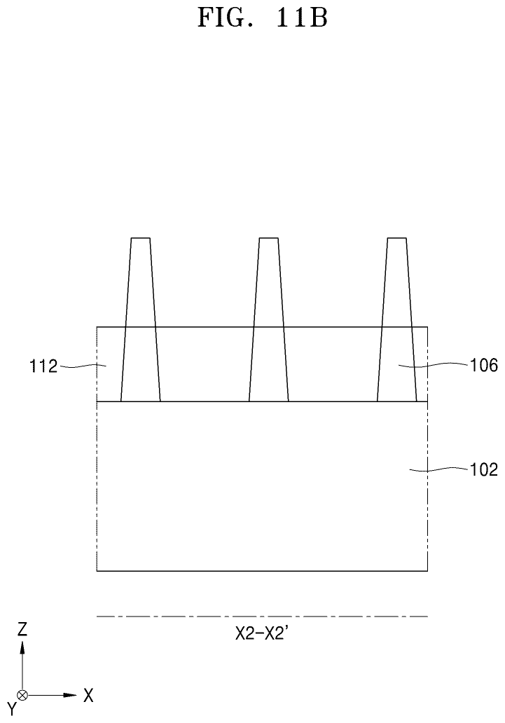

Referring to FIGS. 11A and 11B, in a resultant structure of FIGS. 10A and 10B, the device isolation films 112 covering both side walls of the first fin-type structure 104 and the second fin-type structure 106 may be formed. In embodiments, the device isolation films 112 may at least partially cover a side wall of the lower fin-type structure 104a of the first fin-type structure 104, and may not cover a side wall of the upper fin-type structure 104b. In optional or additional embodiments, the device isolation films 112 may at least partially cover a side wall of the lower fin-type structure 104a and at least a part of a side wall of the upper fin-type structure 104b of the first fin-type structure 104.

Referring to FIGS. 12A, 12B, and 12C, in a resultant structure of FIGS. 11A and 11B, a dummy gate structure DGS may be formed on the first fin-type structure 104 and the second fin-type structure 106. The dummy gate structure DGS may extend along the first horizontal direction (X direction). The dummy gate structure DGS may have a structure in which an oxide film D122, a dummy gate layer D124, and a capping layer D126 are sequentially stacked. In embodiments, the dummy gate layer D124 may be formed of polysilicon, and the capping layer D126 may be formed of a silicon nitride (SIN) film. Subsequently, the insulating spacers 150 at least partially covering both side walls of each of a plurality of dummy gate structures DGS may be formed.

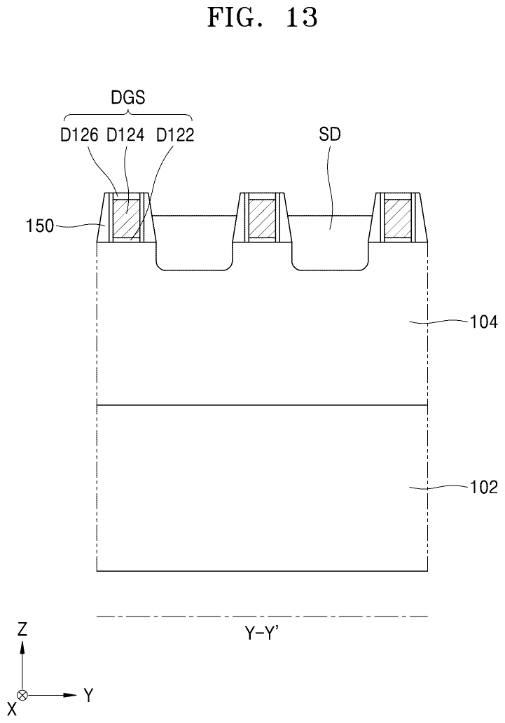

Referring to FIG. 13, in a resultant structure of FIGS. 12A and 12B, parts of the first fin-type structure 104 and the second fin-type structure 106 may be removed by using the plurality of dummy gate structures DGS and the insulating spacers 150 as an etch mask, and a plurality of source/drain regions SD may be formed. In embodiments, parts of the first fin-type structure 104 and the second fin-type structure 106 may be etched by using dry etching, wet etching, and/or a combination thereof. In embodiments, the plurality of source/drain regions SD may be formed by epitaxially growing a semiconductor material from side walls of the first fin-type structure 104 and the second fin-type structure 106.

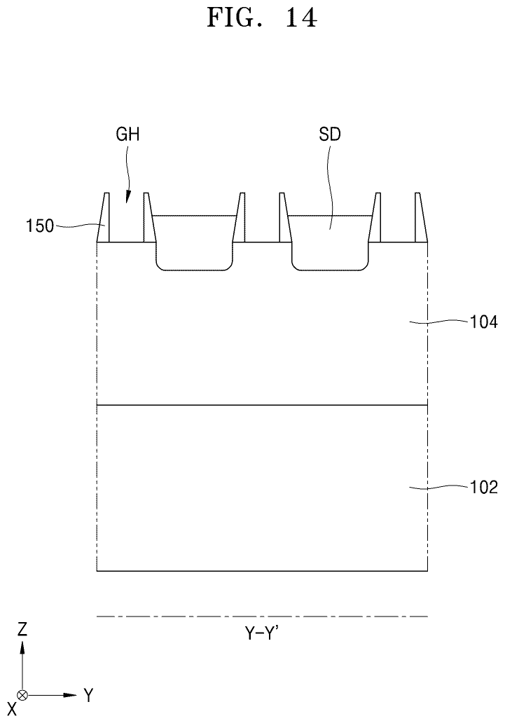

Referring to FIG. 14, in a resultant structure of FIG. 13, a gate space GH may be formed by sequentially removing the oxide film D122, the dummy gate layer D124, and the capping layer D126.

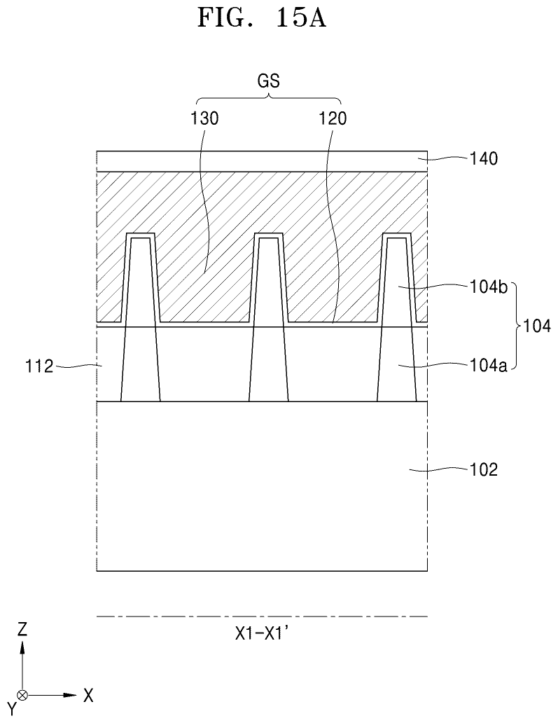

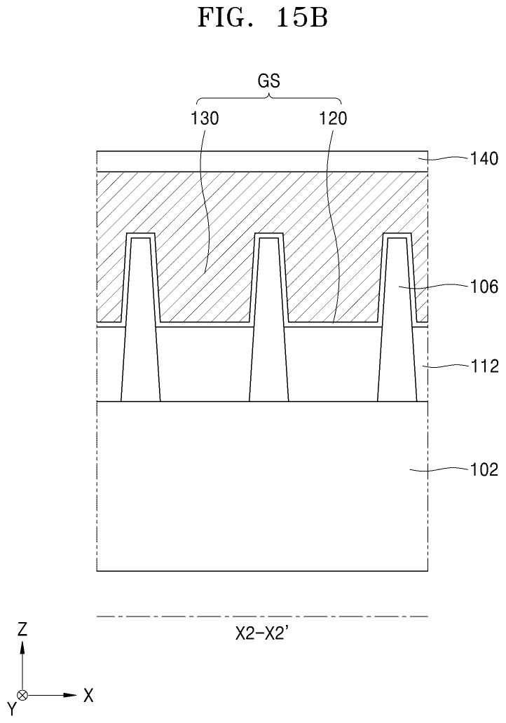

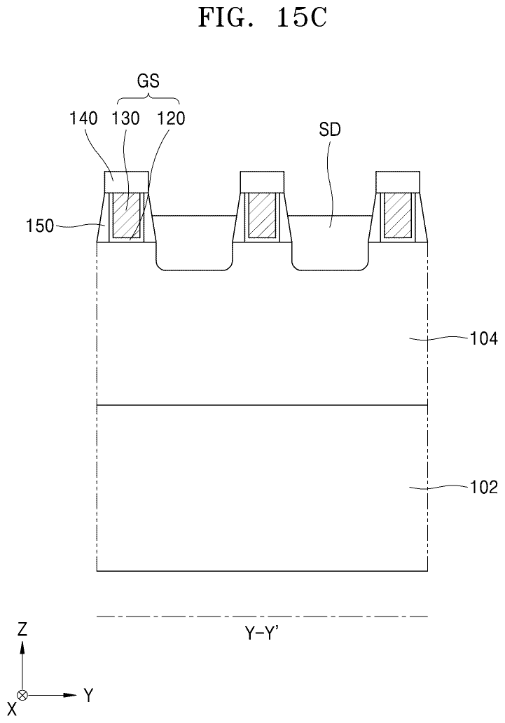

Referring to FIGS. 15A, 15B, and 15C, in a resultant structure of FIG. 14, the gate dielectric film 120 covering an exposed surface of each of the first fin-type structure 104 and the second fin-type structure 106 may be formed. Subsequently, the gate line 130 covering the gate space GH may be formed on the gate dielectric film 120. In an embodiment, the capping layer 140 at least partially covering the gate line 130 and the gate dielectric film 120 may be subsequently formed.

In a resultant structure of FIGS. 15A, 15B, and 15C, the semiconductor device 100 of FIGS. 2A, 2B, and 2C may be manufactured by forming the inter-gate insulating film 160 covering the gate line 130.

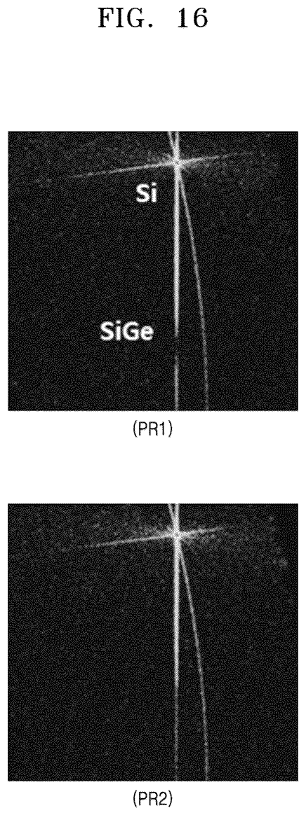

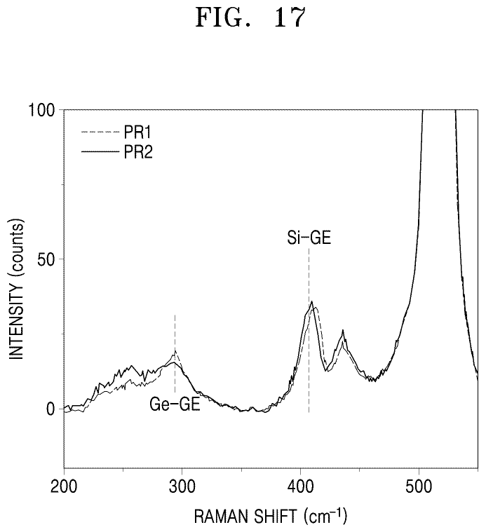

In the method of manufacturing the semiconductor device 100, according to embodiments, the upper fin-type structure 104b of the first fin-type structure 104 may not be formed by forming a material layer including germanium (Ge) through an epitaxial growth process from a top surface of the substrate 102 and etching the material layer, but may be formed by forming the semiconductor material layer 103 including germanium (Ge) on a top surface of the substrate 102, diffusing the germanium (Ge) to an upper portion of the substrate 102 adjacent to the semiconductor material layer 103 to form the diffusion material layer 104P including germanium (Ge) in the upper portion, and etching the diffusion material layer 104P. As the upper fin-type structure 104b may be formed without using epitaxial growth, manufacturing costs of the semiconductor device 100 may be reduced, thereby potentially improving the manufacturing efficiency of the semiconductor device 100, when compared with a related semiconductor device. Alternatively or additionally, silicon-germanium (SiGe) included in the upper fin-type structure 104b may have equal crystallinity and relatively high film quality when compared to fin-type structure formed by using epitaxial growth. The crystallinity and film quality of the upper fin-type structure 104b included in the semiconductor device 100 manufactured, according to embodiments, is described with reference to FIGS. 16 and 17.

FIG. 16 is a view illustrating crystallinity in an embodiment and a comparative example, according to embodiments. FIG. 17 is a graph illustrating a result value of Raman analysis in the embodiment and the comparative example, according to embodiments. In FIGS. 16 and 17, the comparative example may refer to a silicon-germanium (SiGe) film formed by epitaxial growth, and the embodiment may refer to a silicon-germanium (SiGe) film formed according to at least part of the method of manufacturing the semiconductor device 100 described with reference to FIGS. 5 to 8. In FIGS. 16 and 17, PR1 may indicate the comparative example, and PR2 may indicate the embodiment example.

Referring to FIG. 16, when an image of the comparative example PR1 is compared with an image of the embodiment PR2, it may be understood that crystallinity of silicon-germanium (SiGe) in the comparative example and crystallinity of silicon-germanium (SiGe) in the embodiment are equal and/or substantially similar to each other.

Referring to FIG. 17, it may be understood that an intensity of a germanium-germanium (Ge—Ge) bond in the comparative example PR1 may be higher than an intensity of a germanium-germanium (Ge—Ge) bond in the embodiment PR2, and an intensity of a silicon-germanium (SiGe) bond in the comparative example PR1 may be less than or equal to an intensity of a silicon-germanium (Si—Ge) bond in the embodiment PR2. Considering that the comparative example PR1 and the embodiment PR2 include silicon-germanium (SiGe) films whose formation methods are different from each other, it may be understood that the embodiment PR2 having a lower germanium-germanium (Ge—Ge) bond intensity while having substantially the same and/or higher silicon-germanium (SiGe) bond intensity may have an improved film quality over the comparative example PR1.

That is, referring FIGS. 16 and 17 together, it may be understood that a silicon-germanium (SiGe) film in the embodiment PR2 may have substantially the same crystallinity as a silicon-germanium (SiGe) film in the comparative example PR1 and may have an improved film quality when compared with the comparative example PR1.

Embodiments have been disclosed in the drawings and the specification as above. While embodiments have been described using specific terms, this is only used for the purpose of explaining the technical idea of the present disclosure and is not used to limit the meaning and scope of the disclosures described in the claims. While the present disclosure has been particularly shown and described with reference to embodiments thereof, it may be understood by one of ordinary skill in the art that various changes in form and details may be made therein without departing from the spirit and scope of the present disclosure.

What is claimed is:

1. A method of manufacturing a semiconductor device, the method comprising:
forming, on a substrate, a semiconductor material layer comprising germanium;
forming a diffusion material layer in an upper portion of the substrate adjacent to the semiconductor material layer by performing a first heat treatment on the semiconductor material layer;
removing the semiconductor material layer on which the first heat treatment has been performed;
recrystallizing the diffusion material layer by performing a second heat treatment on the diffusion material layer; and
forming a fin-type structure by removing at least a portion of the substrate and at least a portion of the diffusion material layer,
wherein the diffusion material layer comprises at least a portion of germanium diffused from the semiconductor material layer by the performing of the first heat treatment, and
wherein a germanium concentration in the fin-type structure decreases from an upper surface of the fin-type structure toward a lower surface of the fin-type structure along a vertical direction perpendicular to a top surface of the substrate.

2. The method of claim 1, wherein the forming of the semiconductor material layer comprises performing at least one of a thermal deposition and a plasma deposition.

3. The method of claim 2, wherein the thermal deposition comprises at least one of a thermal chemical vapor deposition (CVD) and a thermal atomic layer deposition (ALD), and
wherein the plasma deposition comprises at least one of a plasma-enhanced chemical vapor deposition (PECVD) and a plasma-enhanced atomic layer deposition (PEALD).

4. The method of claim 1, wherein the forming of the semiconductor material layer comprises:
forming a silicon material layer; and
implanting germanium ions into the silicon material layer.

5. The method of claim 1, wherein the semiconductor material layer comprises a plurality of semiconductor material layers, and
wherein a first germanium atomic concentration in first layer of the plurality of semiconductor material layers is different from germanium atomic concentrations in remaining layers of the plurality of semiconductor material layers.

6. The method of claim 1, further comprising:
forming an anti-diffusion layer on the semiconductor material layer, and
wherein the anti-diffusion layer comprises at least one of silicon oxide, silicon nitride, and polysilicon.

7. The method of claim 1, wherein the performing of the first heat treatment comprises performing the first heat treatment at a temperature range between about 600° C. to about 900° C. for a time duration between about 5 minutes to about 20 minutes.

8. The method of claim 1, wherein the performing of the second heat treatment comprises performing at least one of a spike rapid thermal annealing (RTA) process, a laser annealing process, and a flash lamp annealing process.

9. The method of claim 1, wherein a first germanium concentration in the fin-type structure at a first vertical level of the fin-type structure is substantially similar across the first vertical level of the fin-type structure.

10. A method of manufacturing a semiconductor device, the method comprising:
forming, on a substrate, a first mask pattern exposing a first area of the substrate, the substrate comprising the first area and a second area;
forming a semiconductor material layer on the first area exposed by the first mask pattern, the semiconductor material layer comprising germanium;
forming a diffusion material layer in an upper portion of the first area of the substrate adjacent to the semiconductor material layer by performing a first heat treatment on the semiconductor material layer;
removing the first mask pattern and the semiconductor material layer on which the first heat treatment has been performed;
recrystallizing the diffusion material layer by performing a second heat treatment on the diffusion material layer;
forming, on the substrate, a second mask pattern exposing at least a portion of the first area and at least a portion of the second area;
forming, using the second mask pattern, a first fin-type structure on the first area; and
forming, using the second mask pattern, a second fin-type structure on the second area,
wherein the diffusion material layer comprises at least a portion of germanium diffused from the semiconductor material layer by the performing of the first heat treatment, and
wherein an upper surface of the first fin-type structure and an upper surface of the second fin-type structure are located at a substantially similar vertical level.

11. The method of claim 10, wherein the first area comprises a P-channel metal-oxide semiconductor (PMOS) area where a P-type channel is formed, and
wherein the second area comprises an N-channel metal-oxide semiconductor (NMOS) area where an N-type channel is formed.

12. The method of claim 10, wherein a first height of the first fin-type structure in a vertical direction perpendicular to a top surface of the substrate is substantially similar to a second height of the second fin-type structure in the vertical direction.

13. The method of claim 10, wherein the first fin-type structure comprises silicon and germanium, and
wherein the second fin-type structure comprises silicon.

14. The method of claim 13, wherein a germanium concentration in the first fin-type structure decreases from the upper surface of the first fin-type structure toward a lower surface of the first fin-type structure along a vertical direction perpendicular to a top surface of the substrate.

15. The method of claim 10, wherein the forming of the semiconductor material layer comprises performing at least one of a thermal deposition and a plasma deposition,
wherein the thermal deposition comprises at least one of a thermal chemical vapor deposition (CVD) and a thermal atomic layer deposition (ALD), and
wherein the plasma deposition comprises at least one of a plasma-enhanced chemical vapor deposition (PECVD) and a plasma-enhanced atomic layer deposition (PEALD).

16. The method of claim 10, further comprising:
forming an anti-diffusion layer on the semiconductor material layer, and
wherein the anti-diffusion layer comprises at least one of silicon oxide, silicon nitride, and polysilicon.

17. The method of claim 10, wherein the performing of the first heat treatment comprises performing the first heat treatment at a temperature range between about 600° C. to about 900° C. for a time duration between about 5 minutes to 20 minutes.

18. The method of claim 10, wherein the performing of the second heat treatment comprises performing at least one of a spike rapid thermal annealing (RTA) process, a laser annealing process, and a flash lamp annealing process.

19. A method of manufacturing a semiconductor device, the method comprising:
forming, on a substrate, a first mask pattern exposing a first area of the substrate, the substrate comprising the first area and a second area;
forming a semiconductor material layer and an anti-diffusion layer on the first area exposed by the first mask pattern, the semiconductor material layer comprising germanium;
forming a diffusion material layer in an upper portion of the first area of the substrate adjacent to the semiconductor material layer by performing a first heat treatment on the semiconductor material layer;
removing the semiconductor material layer, the anti-diffusion layer, and the first mask pattern;
recrystallizing the diffusion material layer by performing a second heat treatment on the diffusion material layer on the first area;
forming, on the substrate, a second mask pattern exposing at least a portion of the first area and at least a portion of the second area;
forming, using the second mask pattern, a first fin-type structure in the first area by removing at least a portion of the substrate and at least a portion the diffusion material layer; and
forming, using the second mask pattern, a second fin-type structure in the second area by removing at least another portion of the substrate,
wherein the diffusion material layer comprises at least a portion of germanium diffused from the semiconductor material layer by the performing of the first heat treatment,
wherein a germanium concentration in the first fin-type structure decreases from an upper surface of the first fin-type structure toward a lower surface of the first fin-type structure along a vertical direction perpendicular to a top surface of the substrate, and
wherein the upper surface of the first fin-type structure and an upper surface of the second fin-type structure are located at a substantially similar vertical level.

20. The method of claim 19, wherein the first area comprises a P-channel metal-oxide semiconductor (PMOS) area where a P-type channel is formed, and
wherein the second area comprises an N-channel metal-oxide semiconductor (NMOS) area where an N-type channel is formed.
